(19) United States
(12) Patent Application Publication
(10) Pub. No.: US 2021/0248844 A1
(43) Pub. Date: Aug. 12, 2021

(54) ADVANCED BATTERY HEALTH DIAGNOSTIC

(71) Applicants: CPS TECHNOLOGY HOLDINGS LLC, New York, NY (US); CLARIOS GERMANY GMBH & CO. KGAA, Hannover (DE); CLARIOS ADVANCED SOLUTIONS GMBH, Hannover (DE)

(72) Inventors: Mark D. GUNDERSON, Bristol, WI (US); Diego Hernan DIAZ MARTINEZ, Milwaukee, WI (US); Samuel F. FREEMAN, Milwaukee, WI (US); Chee Wee GAN, Johns Creek, GA (US); Julie C. ROBERTS, Cedarburg, WI (US); Thomas M. WATSON, Plymouth, MI (US); Sepehr SHIRAZI, Hannover (DE); Ingo KOCH, Hameln (DE); Markus HOH, Wunstorf (DE); Briana KELLY, Shorewood, WI (US)

(21) Appl. No.: 17/268,075

(22) PCT Filed: Aug. 14, 2019
(86) PCT No.: PCT/US2019/046534

§ 371 Date: Feb. 11, 2021

Related U.S. Application Data
(60) Provisional application No. 62/718,796, filed on Aug. 14, 2018.

(51) Int. Cl. G07C 5/08; G07C 5/00; B60R 16/023; B60R 16/033; B60Q 9/00; G01R 31/392; G01R 31/3835; G01R 31/371; G01R 31/367

(52) U.S. Cl. CPC G07C 5/0808; G07C 5/006; B60R 16/0232; B60R 16/033; G01R 31/367; G01R 31/392; G01R 31/3835; G01R 31/371; B60Q 9/00

(57) ABSTRACT

A battery health diagnostic system is disclosed, wherein the battery health diagnostic system comprises a battery, the battery configured to be provided in a vehicle having a vehicle state; a sampling device in electrical communication with the battery and configured to acquire battery characteristic data during a vehicle state; a processor in communication with the device, the processer configured to analyze battery characteristic data to produce a battery condition output; and an alert device configured to provide the battery condition output during regular use of a vehicle.

### BACKGROUND

The performance requirements of batteries have changed with evolving vehicle technologies. For example, many recent vehicles are equipped with technology which shuts down the engine when the vehicle is at rest/stopped (for example, at a stoplight). This feature is known as “start-stop technology” and aims to reduce fuel consumption and idle emissions. Typically, a vehicle will continue to provide internal functions (air conditioning/heat, radio, etc.) while the engine is turned off during a start-stop event. Then, when the vehicle is no longer at rest/stopped, the engine is restarted. Start-stop functionality creates strain on the battery. Starting the vehicle creates a draw on the battery, as does maintaining vehicle functionality while the engine is off. An important function of batteries is therefore to facilitate the start-stop events and to support subsequent load.

Another important function of the battery is the starting of the vehicle when it is at rest, or cold start function of the vehicle. The load in that instance may be heavier when the engine is cold. Start-stop and cold start loads can be different and require different functionality from the battery. Therefore, regular evaluation of battery health has become even more important.

Currently, battery health testing is typically performed by a technician having specialized equipment. The equipment may perform what is known as a load test which evaluates whether a certain load (voltage) can be sustained for a particular period of time. The equipment may need to be connected directly to the battery. This may require, for example, popping the hood of the vehicle to attach a multi-meter or a specialized device. Other systems for monitoring battery health may be found in, for example, U.S. Pat. Nos. 7,061,246 and 6,727,708. Alternatively, a vehicle owner may evaluate battery health by turning on their headlights, starting their vehicle, and looking at whether the headlights dim. If the headlights dim, there may be problems with the battery.

There are various drawbacks to these methods, including the lack of regular feedback, need for expensive equipment, and/or lack of accuracy.

### SUMMARY

Accordingly, an improved diagnostics system is disclosed. The vehicle diagnostics system may evaluate battery health by tracking battery characteristics during a vehicle event or use. The vehicle event may constitute battery use during vehicle operation. Over time, the battery may become less efficient at facilitating vehicle functionality, exhibiting certain battery characteristics that may be predictive of battery failure. Battery failure may include the inability to perform necessary battery capabilities or provide sufficient power for a sufficient amount of time.

The disclosed improved diagnostics system may allow for the prediction of battery failure over time. The disclosed improved diagnostics system may, in various embodiments, allow for regular evaluation of battery health using hardware that can be provided inside the vehicle using the vehicle's On-Board Diagnostics (OBD) port. This configuration may allow for convenient and regular testing.

The use of a sampling device with the on-board diagnostics port such as an OBD-II reader or similarly-capable device may also allow for data transmission to a server for data analysis. The OBD-II reader may therefore be provided with a data-transmission device for wireless transmission of data.

Disclosed herein is a battery health diagnostic system comprising: a battery, the battery configured to be provided in a vehicle having a vehicle state; a sampling device in electrical communication with the battery and configured to acquire battery characteristic data during a vehicle state; a processor in communication with the device, the processer configured to analyze battery characteristic data to produce a battery condition output; and an alert device configured to provide the battery condition output during regular use of a vehicle. Further disclosed herein is a battery health diagnostic wherein the battery condition output is an indicator to allow the user to know when to take action regarding the battery. Further disclosed herein is a battery health diagnostic wherein the battery characteristic data is a voltage. Further disclosed herein is a battery health diagnostic wherein the sampling device is an OBD-III reader. Further disclosed herein is a battery health diagnostic wherein the processor is configured to perform a comparator function which compares historical battery status data and battery characteristic data comprising a battery status from vehicle condition data. Further disclosed herein is a battery health diagnostic further comprising a replacement recommendation output provided on the alert device. Further disclosed herein is a battery health diagnostic wherein the battery is provided in a vehicle having the vehicle state. Further disclosed herein is a battery health diagnostic wherein the vehicle state is during operation of the vehicle.

Disclosed herein is a system for obtaining battery data across a fleet of vehicles, the system comprising: a plurality of batteries: a plurality of sampling devices, each sampling device from the plurality of sampling devices being in communication with: a battery from the plurality of batteries; a processor; and a data transmission device; wherein each sampling device from the plurality of sampling devices is further configured to acquire battery characteristic data, the processor is configured to analyze battery characteristic data; and the data transmission device is configured to transmit battery characteristic data; and a server, the server configured to accept battery characteristic data from the plurality of sampling devices and is further configured to analyze battery characteristic data across the plurality of batteries. Further disclosed herein is a system for obtaining battery data across a fleet of vehicles wherein the server reports battery characteristic data across the plurality of batteries. Further disclosed herein is a system for obtaining battery data across a fleet of vehicles wherein the server provides a time to failure estimate for battery health across the fleet of vehicles. Further disclosed herein is a system for obtaining battery data across a fleet of vehicles wherein the plurality of sampling devices are a plurality of OBD-II readers. Further disclosed herein is a system for obtaining battery data across a fleet of vehicles wherein each of the plurality of batteries is provided within a vehicle. Further disclosed herein is a system for obtaining battery data across a fleet of vehicles wherein the vehicle state is during operation of the vehicle. Further disclosed herein is a system for obtaining battery data across a fleet of vehicles wherein the battery characteristic data is a voltage.

The disclosed improved diagnostics system may allow for real-time prognostics regarding battery health. The disclosed improved diagnostics system may allow for the acquisition of battery characteristics data during each vehicle event, which may occur multiple times a day. In addition, the disclosed improved diagnostics system may allow for the analysis of the acquired data each time the data is acquired. The analysis may lead to a possible notification of the driver regarding battery health. The data may also be used for an alert regarding vehicle electrical system condition.

The disclosed improved diagnostics system may allow for driver or user alerts. Beyond the individual driver or user, the disclosed improved diagnostics system may have a variety of further applications, including improvements to supply chain management, regional battery optimization, machine learning to improve predictive capabilities, and more.

These and various further advantages may be understood from the disclosure herein.

### BRIEF DESCRIPTION OF THE FIGURES

FIG. 1 is an illustration of a vehicle having an energy storage system for use with the system and method herein, according to various examples of embodiments.

FIG. 2 is another illustration of a vehicle having an energy storage system for use with the system and method herein, according to various examples of embodiments.

FIG. 3 is a diagram of system components, according to various examples of embodiments.

FIG. 4 is a workflow of the system, according to various examples of embodiments.

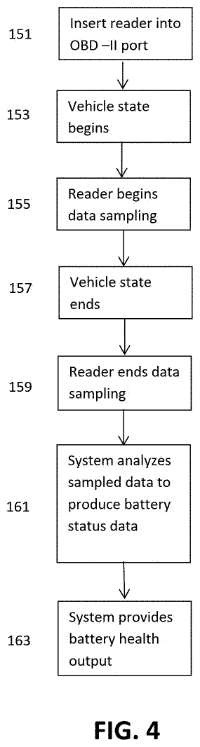

FIG. 5 is a diagram of system components, according to various examples of embodiments.

FIG. 6 is a user interface for a mobile device for use with the system and method herein, according to various examples of embodiments.

It should be understood that the drawings are not necessarily to scale. In certain instances, details that are not necessary to the understanding to the invention or render other details difficult to perceive may have been omitted. It should be understood, of course, that the invention is not necessarily limited to the particular embodiments illustrated herein.

### DETAILED DESCRIPTION

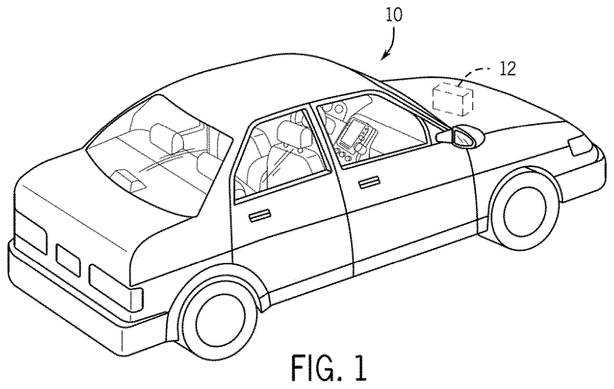

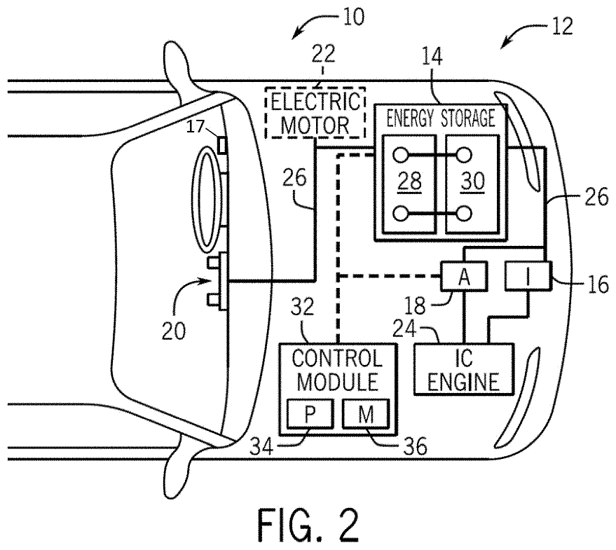

To help illustrate, FIG. 1 is a perspective view of an embodiment of a vehicle 10. A battery system 12 may be seen in the vehicle 10; a more detailed view of the battery system 12 is described in FIG. 2. As depicted in FIG. 2, the battery system 12 includes an energy storage component 14 coupled to an ignition system 16, an alternator 18, a vehicle console 20, and optionally to an electric motor 22. Generally, the energy storage component 14 may capture/store electrical energy generated in the vehicle 10 and output electrical energy to power electrical devices in the vehicle 10.

In other words, the battery system 12 may supply power to components of the vehicle's electrical system, which may include radiator cooling fans, climate control systems, electric power steering systems, active suspension systems, auto park systems, electric oil pumps, electric super/turbochargers, electric water pumps, heated windscreen/defrosters, window lift motors, vanity lights, tire pressure monitoring systems, sunroof motor controls, power seats, alarm systems, infotainment systems, navigation features, lane departure warning systems, electric parking brakes, external lights, or any combination thereof. Illustratively, in the depicted embodiment, the energy storage component 14 supplies power to the vehicle console 20 and the ignition system 16, which may be used to start (e.g., crank) the vehicle.

Additionally, as depicted, the energy storage component 14 may include multiple battery modules. For example, in the depicted embodiment, the energy storage component 14 includes a first battery module 28 and a second battery module 30, which each includes one or more battery cells. In other embodiments, the energy storage component 14 may include any number of battery modules. To facilitate controlling the capturing and storing of electrical energy, the battery system 12 may additionally include a control module 32. Accordingly, the control unit 32 may include one or more processors 34 and one or more memory 36. An OBD port 17 may be seen in the vehicle dash.

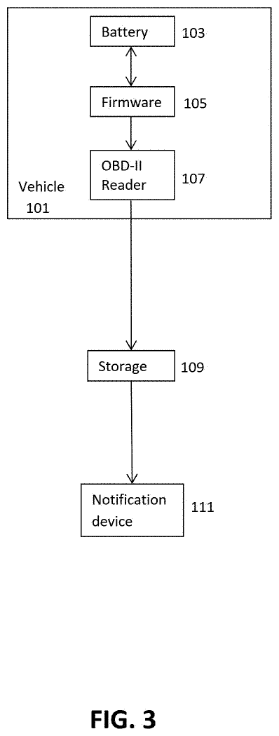

FIG. 3 shows a hardware system. The system may comprise a vehicle 101 having a battery 103 and vehicle firmware 105. The system may further include an OBD-II reader 107. It may be generally understood the disclosed improved diagnostics system may be used, in various embodiments, with an On-Board Diagnostics II (ODB-II) protocol reader 107 though other mechanisms of obtaining and storing data should likewise be considered as within the scope of this disclosure.

OBD-II readers 107 are generally known. Modern cars (for example, vehicle 101) are manufactured with On-Board Diagnostics systems. These diagnostics systems are typically accessible through a port provided on the vehicle 101. OBD-II readers 107 obtain vehicle status information from the vehicle firmware 105 through the port. Different makes and models may have differences in vehicle firmware 105, which may result in different methods and types of vehicle status information being communicated to the OBD-II reader 107. The vehicle firmware 105 may be configured to evaluate systems throughout the vehicle 101, including the battery 103. The firmware 105 may then make battery characteristic or status data 183 which may comprise one or more battery characteristics (e.g. voltage, current, etc.) available to the OBD-II reader 107. In various embodiments, the battery 103 may be a lead-acid battery.

A sampling device 107 such as an OBD-II reader or like mechanism for obtaining vehicle status data may be configured using the system and method herein for regular sampling of battery data (battery status data 183). It should be understood sampling device 107 is in electrical communication with the vehicle, for example, by way of the OBD port 70. Regular sampling may include whenever the vehicle 101 is in use. This may allow for regular user feedback regarding battery health information. The battery data 183 can include vehicle firmware battery status data, battery characteristics, or direct battery signal data, in various embodiments. The sampling device 107 such as an OBD-II reader may be configured to sample battery 103 characteristics. In various embodiments, the sampling device may have a direct line into the power function of the vehicle 101 as it may obtain power from the vehicle through the port 70. In various embodiments, the sampling device may sample battery voltage.

The sampling device such as an OBD-II reader 107 or other suitable device may be equipped to transmit data. In various embodiments, the OBD-II reader 107 may be equipped with a processor and wireless data transmission functionality (for example, wifi, Bluetooth, cellular, or other data transmission mechanism). The vehicle status information may then be transmitted to a storage location (for example, a cloud server) 109 for evaluation of the data. While the term “cloud server” is provided, any suitable computer may be contemplated as within the scope of this disclosure. For example, analysis may take place on a mobile device (such as, but not limited to, notification device 111), the OBD-II 107 reader itself, or other suitably equipped device capable of receiving information gathered from the vehicle firmware 105.

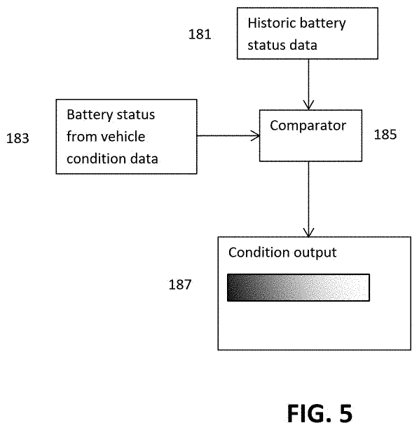

Once the data is transmitted to the cloud (storage 109), analysis of the data (for example, battery characteristic data including battery characteristic during a vehicle event) may occur. The analysis may include applying the algorithm shown and described herein in FIG. 5. The algorithm may output a battery status 187 such as good, marginal, or bad, for example. The gradient shown as an example in 187 may, while shown as black to white, may in various embodiments, be red to green (as a non-limiting example, poor (red) to good (green)). The system may require a certain number of status readings before generating an alert. The alert may be comprised of a push notification or other indicia provided on a user's mobile device (alert device 111). Other alert mechanisms are likewise within the scope of this disclosure.

FIG. 2 shows an example workflow of the system and method herein. First, in step 151, a specialized OBD-II reader is inserted into the vehicle's OBD port. Next, in step 153, a vehicle state such as vehicle operation may occur. The reader in step 155 may begin monitoring battery characteristic(s), for example, by saving battery characteristic data locally on the OBD-II reader itself. The vehicle state may end in step 157. Next, in step 159, the battery characteristic sampling may end and analysis of the data, for example, using FIG. 5 may be performed (step 161). Battery characteristic data and analyzed results may be saved. Finally, in step 163, the system may determine whether to alert. In deciding whether to alert, a plurality of readings may be compared. As a non-limiting example, the system may provide a battery health output. The health output may be provided, for example, after a number of sampling events. For example, a “bad” indication may come after a number of tests have yielded a “bad” battery health result when applying a battery health diagnostic analysis.

FIG. 5 shows an algorithm for use with the system and method herein. Historic battery status data, as well as battery status from vehicle condition data, are compared. In various embodiments, after comparing the data a battery status output may be given to a consumer, which may comprise, in various embodiments, a condition of bad, marginal, or good, or a color indication.

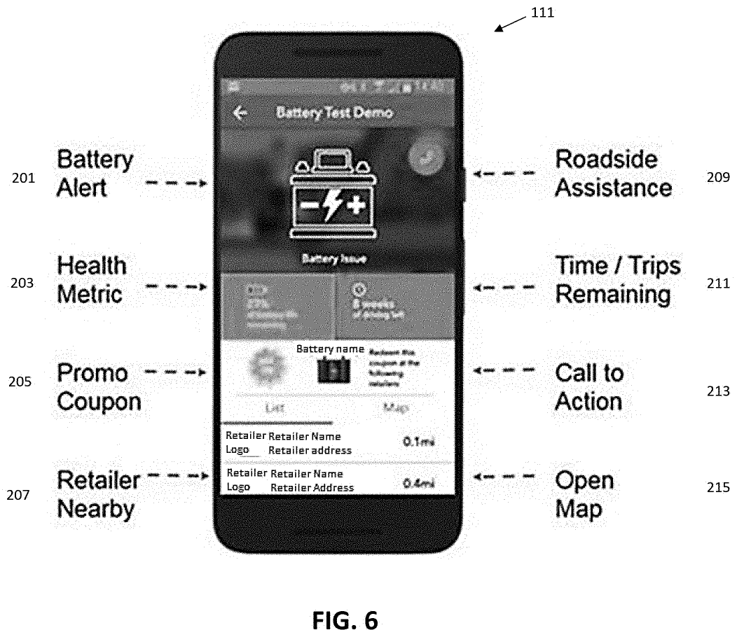

FIG. 6 shows a user interface for use with the system and method herein. The user interface may be provided on a mobile device, in various embodiments. The user interface could provide a battery alert 201, for example, using the system and method herein, indicating to the user that there is an issue with the battery. The user interface, in various embodiments, could provide a button 209 connecting the user to roadside assistance service. The user interface could provide a health metric 203, for example, a percentage of battery health, using the system and method herein. Similarly, the user interface health metric 203 could reflect a time/trips remaining on the user interface, according to various embodiments, using the system and method herein. The user interface could provide a user with a call to action 213, indicating steps needing to be taken to remedy issues, in various embodiments. The user interface could provide the user with additional commercial options, such as but not limited to a promotional coupon 205, retailer information 207, maps to a retailer 215, etc. in order to direct a user to a resource for battery replacement, for example, in various embodiments.

The disclosed system provides various advantages over known battery health diagnostic systems. The system in various embodiments allows for regular battery health evaluation within a vehicle during regular operation of the vehicle. The system may allow for the use of battery health factors and may provide a correlation to good, marginal, and bad battery health. The system may allow for flexibility and customized battery health evaluation. This may, in various embodiments, allow for improved accuracy in battery health diagnosis.

The disclosed improved diagnostics system may allow for a progressive warning system. The progressive warning system may allow for the driver to be warned regarding various states of vehicle condition (such as battery health). For example, the disclosed improved diagnostic system may allow for a prognosis of good battery health (or electrical system condition) based on the results of the analysis. This may appear to the user on a user interface as part of a software, such as a mobile device. The user interface may indicate a condition of “green” for a good result from the analysis, “yellow” for marginal result (or borderline) from the analysis, and “red” for poor results from the analysis. This may allow the user to know when to take action regarding the health of the user's battery. The disclosed improved diagnostics system may therefore allow for real-time prognostics and feedback to drivers or other users regarding possible battery or electrical issues. The device's user interface notification may also help direct drivers to battery vendors when battery condition is poor. The system may also alert roadside assistance such as an insurance company when battery condition is poor, or for example, when there is a failed crank event (the battery will not start the vehicle). Besides good, marginal, or poor, the system could provide a time to failure estimate for the battery to the user based on trends in the battery health analysis. The alert could also provide a recommended battery vendor or location of a battery vendor near the user. The recommendation could be based on, for example, location data such as GPS data provided by the user device or OBD-II reader. The recommendation could compare the location data with a repository of battery vendors and the battery vendor location. The system could then recommend a vendor based on proximity based on battery health status.

The system may allow for a number of advantages beyond individual driver warning. The acquired data may allow for notification to third-party providers or data aggregation across multiple devices/vehicles. In other words, the cloud analysis of battery health may store multiple battery health (for example, but not limited to, OBD-III) readings regarding battery health analysis events. The aggregation of this data may allow for various applications beyond user notification. Further analysis may be performed of the aggregate battery health (for example, OBD-III reader) data in order to facilitate further functionality. The system herein may be advantageous for a variety of applications, including informing regional impact on battery health, supply chain optimization, fleet vehicles, insurance notifications, vendor supply forecasting, and the like. The system could generate an analysis report (for example, by executing a number of data queries and transmitting the results to a software or user interface such as, but not limited to, a web-based application) across the aggregate battery status (for example, OBD-II reader) data. This may be across all devices or readers using the system herein, or across particular selected devices (such as by region, vehicle type, particular vehicles, etc.).

The disclosed system may allow for improved supply chain management. For example, if battery health is indicated as failing or marginal across a large number of vehicles within a region, suppliers may receive a notification of need regarding those batteries. Therefore, the battery failure prediction may allow for vendors to purchase certain additional batteries based on regional battery failure prediction using the system herein. The system herein may also help battery manufacturers predict trends in battery supply requests.

The system herein may also inform vehicle manufacturers regarding battery health trends with their vehicles. For example, if one vehicle type has a disproportionate number of battery health issues, there may be a design issue in the vehicle causing a battery to fail faster.

Fleet vehicle owners may likewise use aggregate information from vehicles across their fleet. In this way, the system could provide battery information across a number of particular vehicles to a centralized fleet owner report. The system could provide a time to failure estimate for battery health across the fleet of vehicles.

These and other advantages and applications may be realized using the system disclosed herein.

It should be noted that references to relative positions (e.g., “top” and “bottom”) in this description are merely used to identify various elements as are oriented in the Figures. It should be recognized that the orientation of particular components may vary greatly depending on the application in which they are used.

For the purpose of this disclosure, the term “coupled” means the joining of two members directly or indirectly to one another. Such joining may be stationary in nature or moveable in nature. Such joining may be achieved with the two members or the two members and any additional intermediate members being integrally formed as a single unitary body with one another or with the two members or the two members and any additional intermediate members being attached to one another. Such joining may be permanent in nature or may be removable or releasable in nature.

It is also important to note that the construction and arrangement of the system, methods, and devices as shown in the various examples of embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements show as multiple parts may be integrally formed, the operation of the interfaces may be reversed or otherwise varied, the length or width of the structures and/or members or connector or other elements of the system may be varied, the nature or number of adjustment positions provided between the elements may be varied (e.g. by variations in the number of engagement slots or size of the engagement slots or type of engagement). The order or sequence of any algorithm, process, or method steps may be varied or re-sequenced according to alternative embodiments. Likewise, some algorithm or method steps described may be omitted, and/or other steps added. Other substitutions, modifications, changes and omissions may be made in the design, operating conditions and arrangement of the various examples of embodiments without departing from the spirit or scope of the present inventions.

While this invention has been described in conjunction with the examples of embodiments outlined above, various alternatives, modifications, variations, improvements and/or substantial equivalents, whether known or that are or may be presently foreseen, may become apparent to those having at least ordinary skill in the art. Accordingly, the examples of embodiments of the invention, as set forth above, are intended to be illustrative, not limiting. Various changes may be made without departing from the spirit or scope of the invention. Therefore, the invention is intended to embrace all known or earlier developed alternatives, modifications, variations, improvements and/or substantial equivalents.

The technical effects and technical problems in the specification are exemplary and are not limiting. It should be noted that the embodiments described in the specification may have other technical effects and can solve other technical problems. Aspects of the method described herein are implemented on a software system running on a computer system. To this end, the methods and system may be implemented in, or in association with, a general-purpose software package or a specific purpose software package. As a specific, non-limiting example, the device could be an OBD-II reader in communication with a cloud storage database and/or mobile device.

The software system described herein may include a mixture of different source codes. The system or method herein may be operated by computer-executable instructions, such as but not limited to, program modules, executable on a computer. Examples of program modules include, but are not limited to, routines, programs, objects, components, data structures, and the like which perform particular tasks or implement particular instructions. The software system may also be operable for supporting the transfer of information within a network.

While the descriptions may include specific devices or computers, it should be understood the system and/or method may be implemented by any suitable device (or devices) having suitable computational means. This may include programmable special purpose computers or general-purpose computers that execute the system according to the relevant instructions. The computer system or portable electronic device can be an embedded system, a personal computer, notebook computer, server computer, mainframe, networked computer, workstation, handheld computer, as well as now known or future developed mobile devices, such as for example, a personal digital assistant, cell phone, smartphone, tablet computer, mobile scanning device, and the like. Other computer system configurations are also contemplated for use with the communication system including, but not limited to, multiprocessor systems, microprocessor-based or programmable electronics, network personal computers, minicomputers, smart watches, and the like. Preferably, the computing system chosen includes a processor suitable for efficient operation of one or more of the various systems or functions or attributes of the communication system described.

The system or portions thereof may also be linked to a distributed computing environment, where tasks are performed by remote processing devices that are linked through a communication network(s). To this end, the system may be configured or linked to multiple computers in a network including, but not limited to, a local area network, wide area network, wireless network, and the Internet. Therefore, information, content, and data may be transferred within the network or system by wireless means, by hardwire connection, or combinations thereof. Accordingly, the devices described herein communicate according to now known or future developed pathways including, but not limited to, wired, wireless, and fiber-optic channels.

In one or more examples of embodiments, data may be stored remotely (and retrieved by the application) or may be stored locally on a user's device in a suitable storage medium. Data storage may be in volatile or non-volatile memory. Data may be stored in appropriate computer-readable medium including read-only memory, random-access memory, CD-ROM, CD-R, CD-RW, magnetic tapes, flash drives, as well as other optical data storage devices. Data may be stored and transmitted by and within the system in any suitable form. Any source code or other language suitable for accomplishing the desired functions described herein may be acceptable for use.

Furthermore, the computer or computers or portable electronic devices may be operatively or functionally connected to one or more mass storage devices, such as but not limited to, a hosted database or cloud-based storage.

The system may also include computer-readable media which may include any computer-readable media or medium that may be used to carry or store desired program code that may be accessed by a computer. The invention can also be embodied as computer-readable code on a computer-readable medium. To this end, the computer-readable medium may be any data storage device that can store data. The computer-readable medium can also be distributed over a network-coupled computer system so that the computer-readable code is stored and executed in a distributed fashion.

1-15. (canceled)

16. A battery health diagnostic system comprising:
a battery, the battery configured to be provided in a vehicle having a vehicle state;
a sampling device in electrical communication with the battery, configured to acquire battery characteristic data during a vehicle state, and configured to wirelessly transmit the battery characteristic data;
a storage location, including a processor, in wireless communication with the sampling device, the processer configured to
receive the battery characteristic data,
analyze the battery characteristic data to produce a battery condition output, wherein the battery condition output includes a battery health metric, and
wirelessly transmit the battery condition output; and
an alert device in wireless communication with the storage location, the alert device configured to
receive the battery condition output, and
provide the battery condition output, including the battery health metric, during regular use of a vehicle.

17. The battery health diagnostic system of claim 16, wherein the battery condition output includes an indicator to allow a user to know when to take action regarding the battery.

18. The battery health diagnostic system of claim 16, wherein the battery characteristic data includes a voltage.

19. The battery health diagnostic system of claim 16, wherein the sampling device includes an OBD-II reader.

20. The battery health diagnostic system of claim 16, wherein the processor is configured to perform a comparator function which compares historical battery status data and battery characteristic data comprising a battery status from vehicle condition data.

21. The battery health diagnostic system of claim 16, wherein the battery health metric includes a time or number of trips remaining for the battery, and wherein the alert device displays the time or n number of trips.

22. The battery health diagnostic system of claim 16, wherein the battery is provided in a vehicle having the vehicle state.

23. The battery health diagnostic system of claim 22, wherein the vehicle state is during operation of the vehicle.

24. A system for obtaining battery data across a fleet of vehicles, the system comprising:
a plurality of batteries:
a plurality of sampling devices, each sampling device from the plurality of sampling devices being in communication with:
a battery from the plurality of batteries;
a processor; and
a data transmission device;
wherein each sampling device from the plurality of sampling devices is further configured to acquire battery characteristic data, the processor is configured to analyze battery characteristic data; and the data transmission device is configured to transmit battery characteristic data; and
a server, the server configured to accept battery characteristic data from the plurality of sampling devices and is further configured to analyze battery characteristic data across the plurality of batteries to determine a time to failure estimate for battery health across the fleet of vehicles.

25. The system of claim 24, wherein the server reports battery characteristic data across the plurality of batteries.

26. The system of claim 24, wherein the plurality of sampling devices are a plurality of OBD-II readers.

27. The system of claim 24, wherein each of the plurality of batteries is provided within a vehicle.

28. The system of claim 24, wherein the battery characteristic data is a voltage.
